(19) United States
(12) Patent Application Publication
(10) Pub. No.: US 2007/0111700 A1
(43) Pub. Date: May 17, 2007

(54) Car type MP3 sound converter

(75) Inventor: Chien-Yuan Chen, Banchiau City (TW)

Correspondence Address: TROXELL LAW OFFICE PLLC, SUITE 1404, 5205 LEESBURG PIKE, FALLS CHURCH, VA, 22041, US

(73) Assignee: Power Digital Communications Co., Ltd.

(21) Appl. No.: 11/271,796

(22) Filed: Nov. 14, 2005

(51) Int. Cl. H05K 11/02; H04B 1/06

(52) U.S. Cl. 455/345

(57) ABSTRACT

The present invention provides a car type MP3 sound converter that includes a case, within which is disposed a MP3 decoder, a frequency modulation transmitter module and a printed-circuit board constructed from related control circuits, wherein the printed-circuit board is further configured with a sound input jack, a sound output jack, a USB connector interface, a memory card connector and a related operating push button set. An electrical connection is made with the cigarette lighter connector on the case, thereby facilitating the car type MP3 sound converter to use a transmission interface of the USB connector interface or the memory card connector to acquire MP3 sound wave data stored in general storage media, whereafter the MP3 decoder implements decoding, and finally the decoded audio signals are transmitted through the frequency modulation transmitter module using a wireless method or are output through the sound output jack.

### BACKGROUND OF THE INVENTION

(a) Field of the Invention The present invention relates to a sound converter, and more particularly to a car type MP3 sound converter that is able to directly transmit MP3 music stored in a peripheral device or a general storage medium through a transmission interface of a USB (Universal Serial Bus) connector interface having an automatic recharging function or a memory card connector. Moreover, the music is transmitted through a frequency modulation transmitter module by means of a wireless method or through a sound output jack.

(b) Description of the Prior Art

All sound formats are digitized and stored using digital coding methods, which can be generally divided into two types including sound wave data and synthesized sound effects (MIDI). Wherein, sound wave data undergoes sampling conversion to a digital format through an analog-to-digital converter, and is then stored in a storage medium of a computer, whereas synthesized sound effects are assembled from a computer built-in sound source. Because the higher the sampling frequency of sound wave data converted to digital format, the larger the storage space required, thus, similarly, the higher the resolution of the sampling, the larger the storage space required.

For example, a common sound wave format is wave data, which is generally stored as a *.wav file. However, the storage space occupied by a file in wave format containing one minute of sound wave data is over 10 MB, which is a considerable waste of storage space. In order to resolve this problem, the MP3 sound wave format was developed that uses MPEG Audio Layer 3 technology, which employs a 10 to 1 or even a 12 to 1 compression ratio to compress the sound wave data, thereby forming a substantially smaller file size. The compression method utilized exploits an inadequacy of human hearing in certain areas, and employs destructive compression to remove high and low audio frequencies that cannot be heard by the human ear, thereby converting the sound wave data into a digital compressed file of substantially smaller size.

Because the storage space required to store a file in MP3 sound wave format is small, the file can be saved to a storage medium including a compact disc, a memory card, a mobile disc, and so on. For this reason, functionality to transmit MP3 has been added to some mobile discs, thereby transforming the mobile disc into a MP3 mobile disc, and enabling a user to play decoded audio signals using an earphone or speakers plugged into an earphone jack (that is, a general sound output jack).

Accordingly, MP3 sound converters designed exclusively for car use have appeared on the market, which enable the car stereo equipment to acquire the decoded audio signals through the MP3 sound converter, and broadcast the sound using speakers connected to the car stereo, thereby providing the car stereo with functionality to play MP3 music. Similar early MP3 sound converters used a cassette tape type adaptor cable to transmit audio signals to the car stereo. However, because of the inconvenience in using the adaptor cable, and the problem of some car stereos not having a cassette-cartridge, thus, the sound converter underwent further improvement to be able to utilize a frequency modulation (FM) transmitter module, which transmitted the audio signals using a wireless method, and a frequency modulation receiver of the car stereo received and broadcasted the music, thereby enhancing applicability and facilitation in use of the car type MP3 sound converter.

However, presently, the majority of car type MP3 sound converters commonly seen on the market are only provided with a convert and transmit mode function, and, thus, are only able to acquire decoded audio signals from devices capable of MP3 broadcasting. Hence, the car stereo is unable to broadcast MP3 music stored in MP3 music storage media commonly used by the general user, such as memory cards, USB mobile discs, and so on.

### SUMMARY OF THE INVENTION

In light of the aforementioned, the present invention provides a car type MP3 sound converter comprising a case having a cigarette lighter connector, within which is disposed a MP3 decoder, a frequency modulation transmitter module and a printed-circuit board constructed from related control circuits, wherein the printed-circuit board is further configured with a sound input jack, a sound output jack, a USB connector interface, a memory card connector and buttons having related operating functions. Moreover, an electrical connection is made with the cigarette lighter connector of the case.

Accordingly, the car type MP3 sound converter of the present invention apart from being provided with a transmission mode and conversion function that enables transmitting audio signals using a wireless method, moreover, a transmission interface of the USB connector interface or the memory card connector is used to acquire MP3 sound wave data stored in general storage media, which the built-in MP3 decoder then decodes and transmits. More particularly, because the present invention is provided with USB automatic recharging and mobile telephone connection functionality, thus, a user can listen to MP3 music while simultaneously recharging a mobile telephone and functioning as a handsfree receiver.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows an exploded structural view of a sound converter according to the present invention.

FIG. 2 shows a block diagram depicting structure of the sound converter according to the present invention.

FIG. 3 shows an elevational view depicting an exterior appearance of the sound converter according to the present invention.

FIG. 4 shows an elevational view depicting an exterior appearance of the sound converter from another viewing angle according to the present invention.

### DETAILED DESCRIPTION OF THE PREFERRED EMBODIMENTS

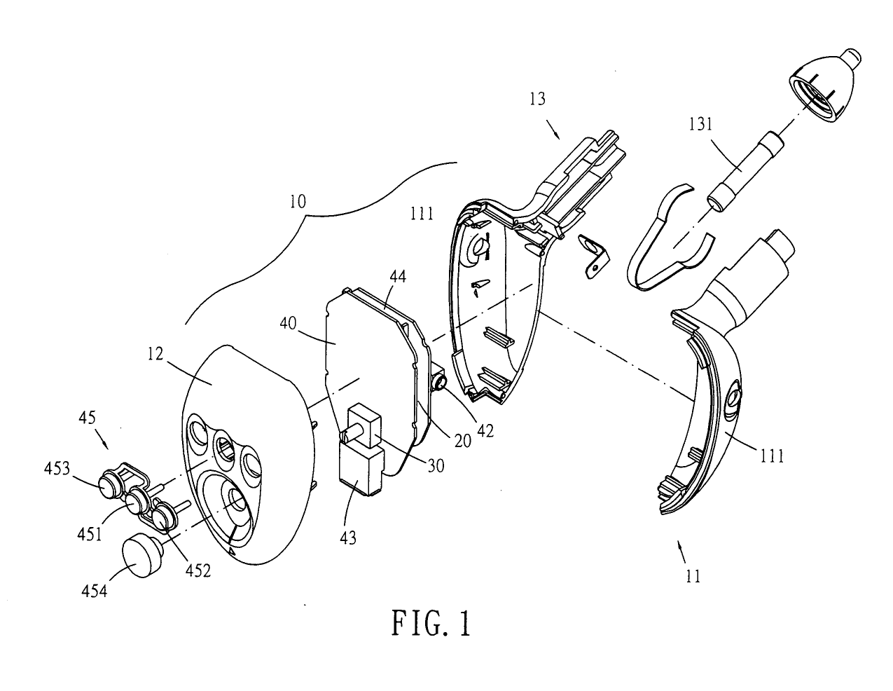

Referring to FIG. 1, which shows the basic structural assembly of a car type MP3 sound converter of the present invention, structured to comprise a case 10, a MP3 decoder 20, a frequency modulation transmitter module 30, and a printed-circuit board 40 constructed from related control circuits.

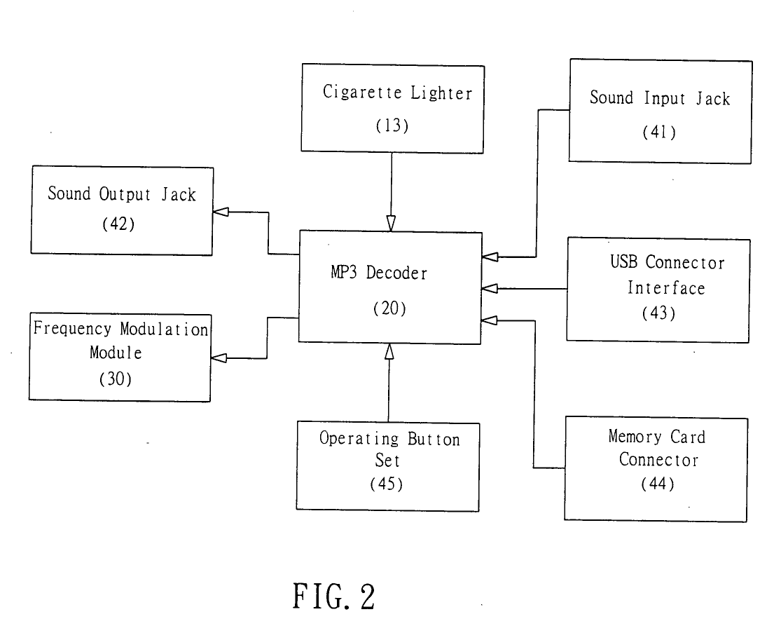

The case 10 is the primary structural body used by the MP3 sound converter for disposing related mechanistic structural members therein. In an embodiment of the present invention, the case 10 is assembled from a base 11 and an upper cover 12, and the base 11 is formed by butt joining two symmetrical lower case covers 111, which forms a cigarette lighter connector 13 after assembling the lower case covers 111, within which is disposed a fuse 131 (see FIG. 2) that facilitates forming an electric outlet connection with a cigarette lighter and acquiring the necessary power supply to operate the sound converter.

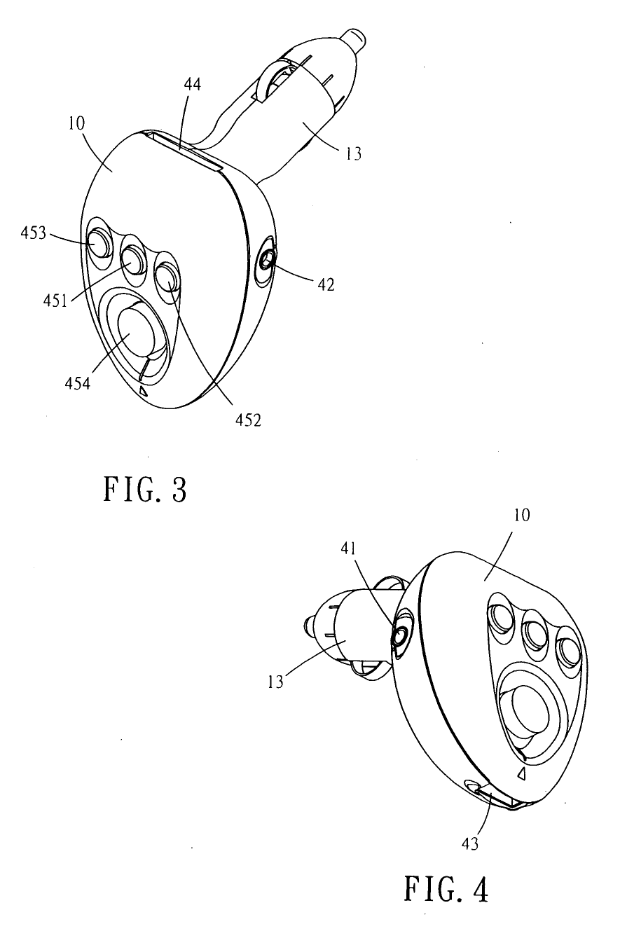

Referring to FIGS. 1, 2, 3 and 4, the MP3 decoder 20 and the frequency modulation transmitter module 30 are directly disposed on the printed-circuit board 40. Moreover, the printed-circuit board 40 is further configured with a sound input jack 41, a sound output jack 42, a USB connector interface 43, a memory card connector 44 and a related operating push button set 45. When an electrical connection is made with the cigarette lighter connector 13 on the case 10, the printed-circuit board 40 then inputs an electrical supply through the cigarette lighter connector 13, whereafter the printed-circuit board 40 integrates circuit functions of the MP3 decoder 20, the frequency modulation module 30 and the operating push button set 45 with the transmission interfaces of sound input jack 41, the sound output jack 42, the USB connector interface 43 and the memory card connector 44.

In an embodiment of the MP3 sound converter of the present invention, the operating push button set 45 comprises a play button 451, next tune switchover button 452, last tune switchover button 453 and a frequency channel selection button 454, and the memory card connector 44 serves as a memory card slot connector for a SD/MMC memory card.

Accordingly, the sound input jack 41 is able to acquire audio signals transmitted by a peripheral device including a portable CD player, a MP3 mobile disc, and so on. Moreover, the audio signals are transmitted through the frequency modulation transmitter module 30 using a wireless method. The transmission interface of the USB connector interface 43 or the memory card connector 44 is then used to acquire the MP3 sound wave data stored in a general storage medium (such as a mobile disc, a memory card, and so on), whereafter the built-in MP3 decoder 20 implements decoding and transmitting of the acquired MP3 sound wave data. The audio signals after undergoing decoding are transmitted through the frequency modulation transmitter module 30 using a wireless method or are output through the sound output jack 42, and earphones or speakers are used to broadcast the sound waves, thereby effectively resolving the problem of car stereos being unable to broadcast MP3 music stored in storage media, such as memory cards, USB mobile discs, and so on.

According to the aforementioned, the present invention provides a superior car type MP3 sound converter, thus, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A car type MP3 sound converter comprising:
a case, within which is disposed related mechanistic structural members, and is further configured with a cigarette lighter connector;
a MP3 decoder, which is configured within the case, and is used to implement decoding and transmitting of input MP3 sound wave data;
a frequency modulation transmitter module, which is configured within the case, and is used to send audio signals being transmitted using a wireless method;
a printed-circuit board, which is configured within the case, and constructed from related control circuits, a sound input jack, a USB connector interface, a memory card connector and a related operating push button set.

2. The car type MP3 sound converter according to claim 1, wherein the case is assembled from a base and an upper cover, the base is formed by butt joining two symmetrical lower case covers, which thereby configures the cigarette lighter connector therefrom.

3. The car type MP3 sound converter according to claim 1, wherein a fuse is configured within the cigarette lighter connector.

4. The car type MP3 sound converter according to claim 1, wherein the MP3 decoder and the frequency modulation module are directly constructed on the printed-circuit board.

5. The car type MP3 sound converter according to claim 1, wherein the operating push button set comprises a play button, next tune switchover button, last tune switchover button and a frequency channel selection button.

6. The car type MP3 sound converter according to claim 1, wherein the memory card connector serves as a memory card slot connector for a SD/MMC memory card.

7. The car type MP3 sound converter according to claim 1, wherein the printed-circuit board is configured with a sound output jack and the sound input jack.

8. The car type MP3 sound converter according to claim 1, wherein the printed-circuit board is further configured with the USB connector interface and a memory card interface.

9. The car type MP3 sound converter according to claim 1, wherein the USB connector interface is provided with an automatic recharging function that enables simultaneous recharging a mobile telephone and broadcasting music.

10. The car type MP3 sound converter according to claim 1, wherein the USB connector interface is provided with handsfree receiver functionality for a mobile telephone.
